(19) United States
(12) Patent Application Publication
(10) Pub. No.: US 2026/0030197 A1
(43) Pub. Date: Jan. 29, 2026

(54) Chiplet Interconnect for High Bandwidth Memory Devices

(71) Applicants: Loke Yip Foo, Bayan Baru (MY); MD Altaf Hossain, Portland, OR (US); Krishna Bharath Kolluru, Hillsboro, OR (US); Lai Guan Tang, Tanjung Bungah (MY)

(72) Inventors: Loke Yip Foo, Bayan Baru (MY); MD Altaf Hossain, Portland, OR (US); Krishna Bharath Kolluru, Hillsboro, OR (US); Lai Guan Tang, Tanjung Bungah (MY)

(21) Appl. No.: 19/341,937

(22) Filed: Sep. 26, 2025

(51) Int. Cl. G06F 15/78; G06F 13/38; H01L 23/00; H01L 23/498

(52) U.S. Cl. CPC G06F 15/7807; G06F 13/382; H01L 23/49816; H01L 24/14; H01L 2224/16146; H01L 2924/15311

(57) ABSTRACT

Systems or methods of the present disclosure may provide communication interfaces for communicatively coupling integrated circuit devices to high bandwidth memory (HBM) devices. In particular, the communication interfaces may support Universal Chiplet Interconnect Express (UCIe) communications between the integrated circuit devices and the HBM devices. The integrated circuit device and the HBM devices may be directly coupled to a communication bridge, such as a package substrate via package substrate bumps. The package substrate may include routing resources that facilitate communications, such as the transmission and reception of UCIe signals, between the integrated circuit device and the HBM device. As a result, the integrated circuit and the HBM devices may engage in low latency communications without demanding any additional hardware interfaces, such as embedded multi-die interconnect bridges (EMIB) or interposers.

### BACKGROUND

The present disclosure relates generally to integrated circuits, such as processors and/or field-programmable gate arrays (FPGAs). More particularly, the present disclosure relates to communications between high bandwidth memory (HBM) devices and integrated circuits, such as FPGAs, based on Universal Chiplet Interconnect Express-Memory (UCIe-M).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Modern electronics, such as computers, portable devices, network routers, data centers, Internet-connected appliances, and the like, tend to include at least one integrated circuit device. Integrated circuit devices may take on a variety of forms, including processors (e.g., central processing units (CPUs)), memory devices, and programmable devices (e.g., FPGA), to name only a few examples. The programmable devices, in particular, may include a programmable fabric of logic that may be programmed (e.g., configured) and reprogrammed (e.g., reconfigured) after manufacturing to provide a wide variety of functionality based on a circuit design.

In certain instances, an integrated circuit device, such as a programmable logic device, may store data to and/or retrieve data from a high bandwidth memory (HBM) device. To decrease data transfer latency, the HBM device and the programmable logic device may be positioned in close proximity. For example, the programmable device and the HBM device may be mounted to a communication bridge. In some cases, for example, the programmable logic device and the HBM device may be mounted to a package substrate, and communicate (e.g., by transmitting signals) through an embedded multi-die interconnect bridge (EMIB) disposed within the package substrate. However, integrating the EMIB into the package substrate may increase complexity of the package substrate and may increase costs associated with the package substrate. Additionally or alternatively, communicating (e.g., transmitting or receiving signals) through the EMIB may increase the data transfer latency between the HBM and the integrated circuit device. In another example, the programmable device and the HBM device may be mounted to an interposer via microbumps and communicate via the interposer. However, the microbumps may be small in size, which may reduce a number of connections (e.g., routing) between the programmable device and the HBM.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit system, in accordance with an embodiment of the present disclosure;

FIG. 2 is a block diagram of an example of the integrated circuit system of FIG. 1, in accordance with an embodiment of the present disclosure;

FIG. 3 is a schematic diagram of an of the integrated circuit system of FIG. 1 including a Universal Chiplet Interconnect Express-Memory (UCIe-M) interface, in accordance with an embodiment of the present disclosure;

FIG. 4 is a block diagram of an example of the integrated circuit system of FIG. 1, where an integrated circuit device of the integrated circuit system of FIG. 1 includes UCIe-M channels, in accordance with an embodiment of the present disclosure;

FIG. 5 is a block diagram of an example of the integrated circuit system of FIG. 1, where an integrated circuit device of the integrated circuit system of FIG. 1 includes 36 UCIe-M channels, in accordance with an embodiment of the present disclosure;

FIG. 6 is a block diagram of an example of the integrated circuit system of FIG. 1, where an integrated circuit device of the integrated circuit system of FIG. 1 includes 54 UCIe-M channels, in accordance with an embodiment of the present disclosure;

FIG. 7 is a block diagram of an example of the integrated circuit system of FIG. 1, where an integrated circuit device of the integrated circuit system of FIG. 1 includes three UCIe-M input/output (I/O), in accordance with an embodiment of the present disclosure;

FIG. 8 is a block diagram of an example of the integrated circuit system of FIG. 1, in accordance with an embodiment of the present disclosure; and

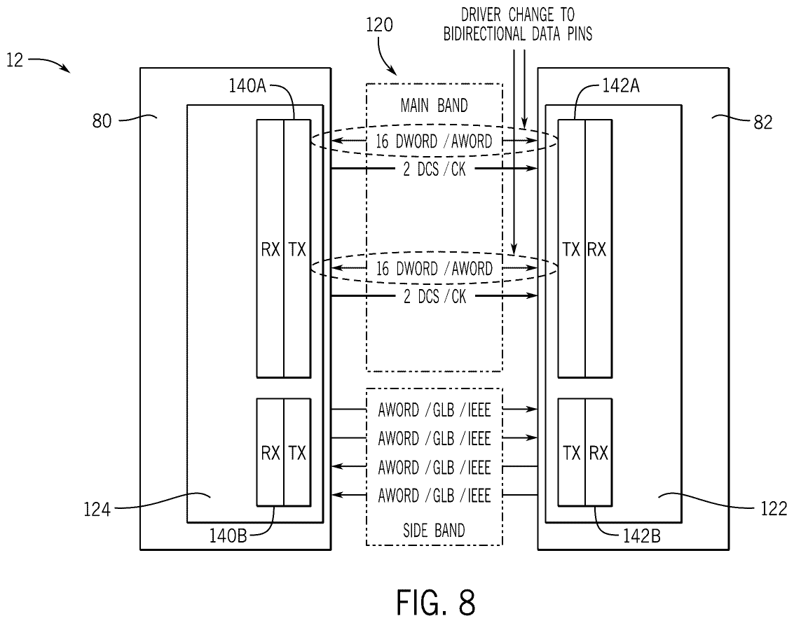

FIG. 9 is a block diagram of a data processing system including the integrated circuit system of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present systems and techniques relate to embodiments of an integrated circuit system that includes an integrated circuit device and a high bandwidth (HBM) device that communicate using Universal Chiplet Interconnect Express-Memory (UCIe-M). The integrated circuit device may include a UCIe-M input/output (I/O) that may be communicatively coupled to the HBM device. In comparison to some communication interfaces, the disclosed communication interface may facilitate data transfer between the integrated circuit device and the HBM device without an interposer, a silicon bridge (e.g., Embedded Multi-Die Interconnect Bridge (EMIB)), and/or microbumps (e.g., relatively small bumps or bonds that are typically between 20-40 microns for interfacing with chips within a multi-die package). As such, the disclosed embodiments may be less complex or more cost effective than alternative communication interfaces.

To facilitate communication between the integrated circuit device and the HBM device, the disclosed embodiments may transmit UCIe-M signals through a communication bridge, such as a package substrate, in which the integrated circuit device and the HBM device may be mounted onto the package substrate. As such, the disclosed embodiments may provide a cost-effective chiplet interconnect through the package substrate. By facilitating communication through the package substrate, the disclosed embodiments provide for an improved IR drop and power delivery network (PDN) performance, which may improve operation of the integrated circuit system and/or reduce power consumption by the integrated circuit system.

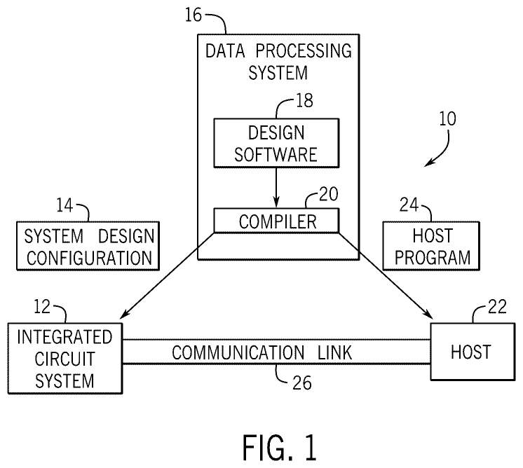

With the foregoing in mind, FIG. 1 illustrates a block diagram of a system 10 that may be used to program an integrated circuit system 12, such as an FPGA (e.g., Agilex™, Stratix®, Arria®, MAX®, or Cyclone® devices by Altera® Corporation), with a system design using a system design configuration 14. Note that, while this disclosure largely refers to the integrated circuit system 12 including programmable logic devices, such as an FPGA, in some embodiments, the integrated circuit system 12 may also include a one-time programmable device or structured application specific integrated circuit (ASIC), such as an Intel® eASIC™ device by Intel® Corporation. In other examples, the integrated circuit system 12 may include any suitable integrated circuit that is manufactured to have a particular system design with circuitry to perform desired data processing operations. The integrated circuit system 12 may include a single monolithic integrated circuit or a multi-die system of integrated circuits. The integrated circuit system 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit system 12. In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In a configuration mode of the integrated circuit system 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit system 12.

Additionally or alternatively, the host 22 running a host program 24 may control or implement the system design configuration 14 onto the integrated circuit system 12. For example, the host 22 may communicate instructions from the host program 24 to the integrated circuit system 12 via a communications link 26 that may include, for example, direct memory access (DMA) communications, peripheral component interconnect express (PCIe) communications, or UCIe-M communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

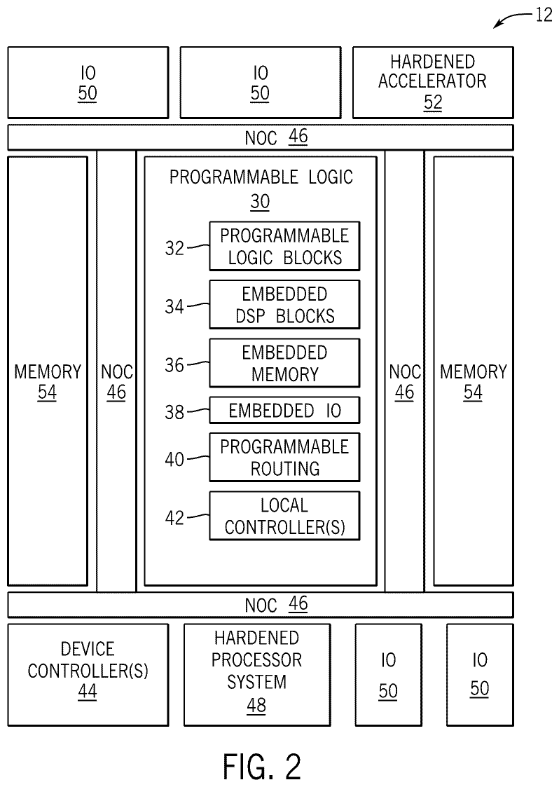

The integrated circuit system 12 may take any suitable form that may implement the system design configuration 14. In one example shown in FIG. 2, the integrated circuit system 12 may include programmable logic circuitry 30, which includes a two-dimensional array of many different functional blocks, such as programmable logic blocks 32, embedded digital signal processing (DSP) blocks 34, embedded memory blocks 36, and embedded input-output (IO) blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any of the programmable logic blocks 32 to implement any desired logic circuitry when programmed (e.g., configured) with the system design configuration 14. The programmable logic blocks 32 and are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 KB, blocks of 1 MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit system 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit system 12. The device controller 44 may include any suitable logic circuitry to control and/or program the programmable logic circuitry 30 or other elements of the integrated circuit system 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 44 may include a hardware finite state machine (FSM). The device controller 44 may provide other functions, such as serving as a platform for virtual machines that may manage the operation of the integrated circuit system 12.

A network-on-chip (NOC) 46 may connect the various elements of the integrated circuit system 12. The NOC 46 may provide rapid, packetized communication to and from the programmable logic circuitry 30 and other blocks, such as a hardened processor system 48, high-speed input-output (IO) blocks 50, a hardened accelerator 52, and local device memory 54. The integrated circuit system 12 may include the hardened processor system 48 when the integrated circuit system 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit system 12. The high-speed IO blocks 50 may enable communication using any suitable communication protocol(s) with other devices outside of the integrated circuit system 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

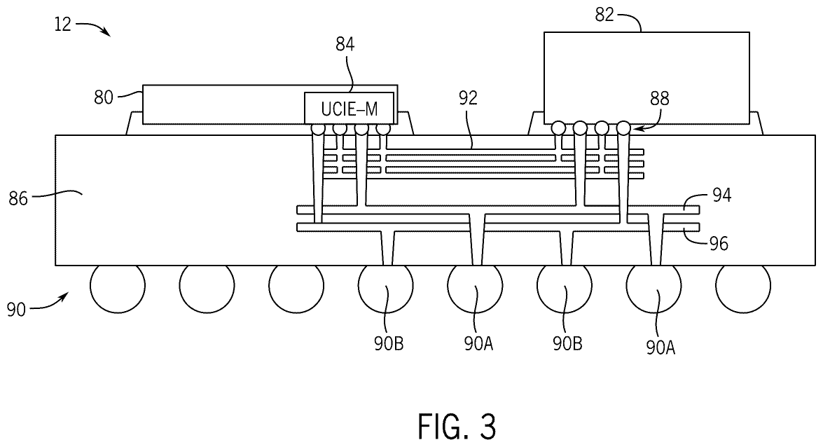

FIG. 3 is a schematic diagram of an example of the integrated circuit system 12 including an integrated circuit device 80 communicatively coupled to a high bandwidth memory (HBM) device 82. The integrated circuit device 80 and the HBM device 82 may communicate via a Universal Interconnect Express (UCIe) standard, such as the UCIe-Memory (UCIe-M) standard. The UCIe-M standard may include a high bandwidth, low-latency interconnect protocol for communicatively coupling memory chiplets (e.g., the HBM device 82) to other integrated circuits. For example, the UCIe-M standard may specify the protocol for data transfers to and from the HBM device 82.

To support communication between the integrated circuit device 80 and the HBM device 82, the integrated circuit device 80 may include an input output (I/O) interface 84, such as a UCIe-M input/output (I/O). For example, the I/O interface 84 may include one of the high-speed IO blocks 50 described with respect to FIG. 2. The I/O interface 84 (e.g., the UCIe-M I/O) may be positioned along an edge of the integrated circuit device 80, on a face of the integrated circuit device 80, or any combination of the two. As further discussed herein, the I/O interface 84 may include one or more channels to support transmitting and/or receiving data from the HBM device 82. For example, the number of channels of the I/O interface 84 may be determined based on a number of channels of the HBM device 82. As the number of channels of the HBM device 82 increases, the number of channels of the I/O interface 84 may increase. For example, two or more HBM devices 82 may be stacked (e.g., in a vertical direction) and may transfer to and/or receive data from one integrated circuit device 80. As illustrated, the integrated circuit device 80 may include a programmable logic device, such as a field programmable gate array (FPGA). However, it should be understood that the integrated circuit device 80 may include any suitable integrated circuit device, and the HBM device 82 may include any suitable memory device.

The integrated circuit device 80 and the HBM device 82 may be coupled to a package substrate 86 via one or more package substrate bumps (PSBs) 88. The PSBs may include package substrate build-ups, controlled collapse chip connection (C4) bumps, microbumps that arc configured to couple to a bump pad to adjust (e.g., increase) the height of the microbumps, or the like. The PSBs 88 may be between 90 to 150 microns in size. Larger PSBs 88 may transmit higher currents in comparison to smaller PSBs 88. The PSBs 88 (e.g., bumps used for interfacing with off-package components) may be substantially larger than in size compared to microbumps (e.g., bumps or bonds used for interfacing with other chips (e.g., chiplets, dies) within the same multi-die package). At least a portion of the PSBs 88 may be coupled to the I/O interface 84 of the integrated circuit device 80 to facilitate signal transfer between the integrated circuit device 80 and the HBM device 82 using UCIe-M communication protocols. To this end, the I/O interface 84 may be positioned at an edge of the integrated circuit device 80, on a face of the integrated circuit device 80, and so on. As illustrated, the I/O interface 84 may be coupled to four PSBs 88. However, it should be understood that the I/O interface 84 may be coupled to any suitable number of PSBs 88. Additionally or alternatively, in some cases existing hardware or circuitry may be configured (e.g., reprogrammed or reconfigured) to implement a standard package system (e.g., an organic package system) between the integrated circuit device 80 and the HBM device 84. For example, in some systems, microbumps may couple the integrated circuit device 80 and/or the HBM device 82 to an EMIB or an interposer (e.g., a silicon (SI) interposer). In some embodiments, the integrated circuit device 80 and/or the HBM device 84 may depopulate a set of the microbumps that couple the integrated circuit device 80 and/or the HBM device 82 to the EMIB or the interposer. Depopulating the microbumps may increase the pitch (e.g., the distance between adjacent microbumps) microbumps, which may enable standard package in non-UCIe systems. For example, depopulating microbumps on existing hardware may enable the integrated circuit device 80 (e.g., or the I/O interface 84 of the integrated circuit device 80) to communicatively couple to the HBM device 82 without the use of an EMIB or an interposer. In these ways, the present techniques may be implemented on existing integrated circuit devices 80 and/or existing HBM devices 82 to enable standard package. Enabling a standard package system between the integrated circuit device 80 and the HBM device 82 may enable communications over the package substrate 86 discussed in this disclosure, which may reduce costs that may be associated with designing, manufacturing, and implementing alternative bridge devices (e.g., EMIBs or SI interposers).

The package substrate 86 may be coupled to one or more ball grid array (BGA) balls 90. The BGA balls 90 may facilitate signal transfer between components of the integrated circuit system 12 and off-package components, provide power to the components of the integrated circuit system 12, provide grounding between the integrated circuit system 12 and a printed circuit board (PCB) that may be coupled to the BGA balls 90, any combination thereof, or the like.

The package substrate 86 may include one or more routing resources to communicatively couple the integrated circuit device 80, the HBM device 82, the BGA balls 90, or any combination thereof. For example, the package substrate 86 may include first routing resources 92 that communicatively couple the integrated circuit device 80 and the HBM device 82. The first routing resources 92 may receive a first signal from the integrated circuit device 80 via a PSB 88 coupled to the integrated circuit device 80 and transmit the signal to the HBM device 82 via another PSB 88, or vice versa. As such, the integrated circuit device 80 and the HBM device 82 may communicate via an organic package substrate (e.g., the package substrate 86). For example, the integrated circuit device 80 and the HBM device 82 may communicate without an intermediary, such as an interposer, an EMIB, and so on, thereby reducing complexity and/or costs of the integrated circuit system 12. In another example, the package substrate 86 may include second routing resources 94 that may couple the integrated circuit device 80 and the HBM device 82 to a first set of BGA balls 90A, respectively. The first set of BGA balls 90A may provide power. The package substrate 86 may also include third routing resources 96 that may couple the integrated circuit device 80 and the HBM device 82 to a second set of BGA balls 90B, respectively. The second set of BGA balls 90B may provide grounding.

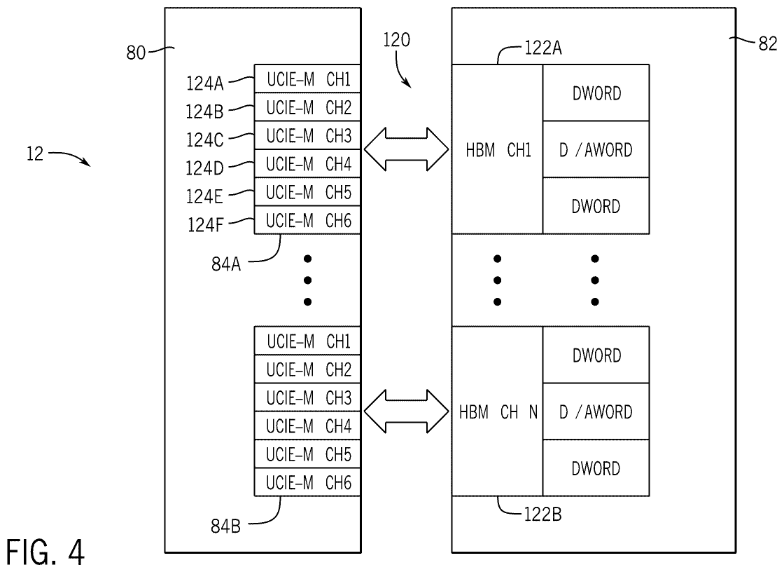

FIG. 4 is a block diagram of an example of the integrated circuit system 12 including an interface 120 between the integrated circuit device 80 and the HBM device 82. The interface 120 may facilitate transmission of UCIe-M signals between the integrated circuit device 80 and the HBM device 82. The UCIe-M signals may include data signals, clock signals, sideband signals, global signals, or any combination thereof.

As illustrated, the integrated circuit device 80 may include a first I/O interface 84A (e.g., a first UCIe-M I/O) that may be communicatively coupled to a first HBM channel 122A of the HBM device 82 and a second I/O interface 84B (e.g., a second UCIe-M I/O) that may be communicatively coupled to a second HBM channel 122B of the HBM device 82. By way of illustrative example, the HBM channel 122 may include 214 pins to support the HBM channel 122 during communication. Continuing with the example, the 214 pins may include 196 signal pins and 18 Data Strobe/Clock (DQS/CK) pins. Data strobe signals may include bidirectional signals used to time data (DQ) transfers between the integrated circuit device 80 and the HBM device 82. The clocking signal may be used to synchronize requests (e.g., commands) and addresses between the integrated circuit device 80 and the HBM device 82. The pins of the HBM channel 122 may operate in a bi-directional mode to transition between a write mode and/or a read mode.

The I/O interface 84 may include two or more UCIe-M channels 124 that include one or more pins that map to the pins of the HBM channel 122. The pins of the UCIe-M channels 124 may include bi-directional pins. For example, HBM clocking pins may be mapped to UCIe-M differential clock pins. In another example, address/command word (AWORD) and/or CK pins of the HBM channel 122 may be mapped to UCIe-M sideband signals.

The I/O interface 84 may transmit and/or receive data in the UCIe-M protocol or in any other suitable communication protocols. The integrated circuit device 80 may include one or more protocol translators that may convert data from the UCIe-M protocol to a protocol used by the integrated circuit device 80, such as a protocol used by programmable logic circuitry of the integrated circuit device 80. The protocol translators may also convert data from the protocol used by the integrated circuit device 80 to the UCIe-M protocol prior to transmitting the data to the I/O interface 84. As such, signaling between the integrated circuit device 80 and the HBM device 82 may be in the UCIe-M protocol.

As illustrated in FIG. 4, the I/O interface 84 may include six UCIe-M channels 124 (illustrated as channels 124A-F) to interface with one HBM channel 122 of the HBM device 82. The UCIe-M channels 124 may communicate with the HBM device 82 using Address/Data Word (D/AWORD) communication and/or Data Word (DWORD) communication. For example, a third UCIe-M channel 124C and a fourth UCIe-M channel 124D may communicate using D/A WORD communication, and the remaining UCIe-M channels 124 (e.g., the first UCIe-M channel 124A, the second UCIe-M channel 124B, the fifth UCIe-M channel 124E, the sixth UCIe-M channel 124F) may communicate using DWORD communication. The DWORD communication and/or the D/AWORD communication may include request for data (e.g., an address), a request to store data, and so on.

To support DWORD communication, for example, the HBM device 82 may transmit Data Queue (DQ) signals, Data Bus Inversion (DBI) signals, Data Mask (DM) signals, Parity (PAR) signals, Data Error (DERR) signals, Redundant Data signals, Write Data Strobe (WDQS) signals, and Read Data Strobe (RDQS) signals. The DQ signals, DBI signals, DM signals, PAR signals, DERR signals, and/or the Redundant Data signals may be mapped to the UCIe-M data signals. The WDQS signals and the RDQS signals may be mapped to UCIe-M clock signals. To support D/AWORD communication, the HBM device 82 may transmit CK signals, Column Command/Address (COL Cmd/Add signals), Row (ROW) Cmd/Add signals, Address Error (AERR) signals, Redundant Row signals, Redundant Column signals, and so on. The CK signal may be mapped to a UCIe-M clock signal. The COL Cmd/Add and the ROW Cmd/Add may be mapped to UCIe-M data signals. The AERR signal, the Redundant Row signal, and the Redundant Column signal may be mapped to UCIe-M sideband signals. By way of example, Table 1 presents a mapping of the UCIe-M data signals for DWORD/DAWORD communications between one HBM channel 122 and six UCIe-M channels 124.

TABLE 1

| | | | | | | UCIe-M |
|---|---|---|---|---|---|---|
| | HBM | | 1 Channel | | | Signal |
| Groups | Signals | Direction | Total | Data | Clock | Mapping |
| DWORD | DQ | I/O | 128 | 128 | | Data |
| | DBI | I/O | 16 | 16 | | Data |
| | DM | I/O | 16 | 16 | | Data |
| | PAR | I/O | 4 | 4 | | Data |
| | DERR | I | 4 | 4 | | Data |
| | Redundant | I/O | 8 | 8 | | Data |
| | Data | | | | | |
| | WDQS | O | 8 | | 8 | CLK |
| | RDQS | I | 8 | | 8 | CLK |
| D/AWORD | CK/CK# | O | 2 | | 2 | CLK |
| | COL | O | 9 | 9 | | Data |
| | Cmd/Add | | | | | |
| | ROW | O | 7 | 7 | | Data |
| | Cmd/Add | | | | | |
| | CKE | O | 1 | 1 | | Sideband |
| | AERR | I | 1 | 1 | | Sideband |
| | Redundant | O | 1 | 1 | | Sideband |
| | Row | | | | | |
| | Redundant | O | 1 | 1 | | Sideband |
| | Column | | | | | |

| | | | |
|---|---|---|---|
| Total | 214 | 196 | 18 |

The UCIe-M signals may operate in two different modes. The first mode may include UCIe-S standard package mode with dedicated Transmission (TX) pin groups and Receive (RX) pin groups. The second mode may include the UCIe-M memory mode which may operate in a bidirectional mode for the data pins to be compatible with the HBM requirement and facilitate the write mode and/or the read mode. Table 2 provides an example of the UCIe-M signals that can operate in the UCIe-S standard package mode or the UCIe-M memory mode for communications between one HBM channel 122 and six UCIe-M channels 124. For example, the UCIe-M signals may include a data signal, a clock signal, a valid signal, a track signal, and/or a sideband/global signal. The data signal may be bi-directional. One UCIe-M channel 124 may include 16 pins to support the signaling, and six UCIe-M channels 124 may include 96 data/sideband pins to support the signaling. The CLK signal may be an output signal (e.g., output by the integrated circuit device 80), and the UCIe-M channel 124 may include 2 clocking pins to support the signal. The valid signal and the track signal may be output signals, and the UCIe-M channel 124 may include one pin to support each signal. The sideband/global signal may be an output signal and the UCIe-M channel 124 may include one data/sideband pin to support the signal.

TABLE 2

| | | | | 6 UCIe-M | |
|---|---|---|---|---|---|
| | | | 1 UCIe-M | Channels | |
| | UCIe-M | Direc- | Channel | Data/ | |
| Groups | Signals | tion | Total | Sideband | Clock |
| UCIe-S | Data | I/O | 16 | 96 | |
| Standard Mode | CLK (Diff) | O | 2 | | 12 |
| (Transmitting) | | | | | |
| UCIe-M | Valid | O | 1 | | |
| memory mode | Track | O | 1 | | |
| (Bididrectional) | Sideband/ | O | 2 | 12 | |
| | Global | | | | |
| UCIe- S | Data | I/O | 16 | 96 | |
| Standard Mode | CLK (Diff) | I | 2 | | 12 |
| (Receiving) | | | | | |
| UCIe-M | Valid | I | 1 | | |
| memory mode | Track | I | 1 | | |
| (Bidirectional) | Sideband/ | I | 2 | 12 | |
| | Global | | | | |
| Total | | | 44 | 216 | 24 |

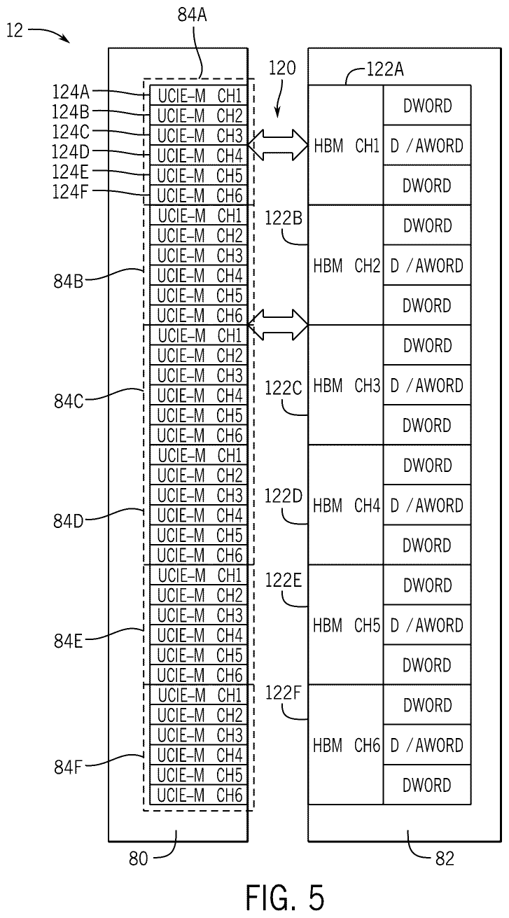

With the preceding in mind, FIG. 5 is a schematic diagram of an example of the integrated circuit system 12 including an interface 120 between the integrated circuit device 80 and the HBM device 82. In the illustrated example, the HBM device 82 may include six HBM channels 122 (illustrated as HBM channels 122A-F). To support communication with the six HBM channels 122, the integrated circuit device 80 may include six I/O interfaces 84 (illustrated as UCIe-M I/O 84A-F) that provide a total of 36 UCIe-M channels 124.

Although the illustrated example includes the I/O interface 84 with six UCIe-M channels 124, it should be understood that the I/O interface 84 may include any suitable number of UCIe-M channels 124 to support communication from the HBM device 82. For example, the number of UCIe-M channels 124 may be determined when designing the integrated circuit system 12, selected by a user (e.g., a designer), and so on. The integrated circuit device 80 may include any suitable number of I/O interfaces 84 to communicate with the HBM device 82.

The integrated circuit device 80 may include a first I/O interface 84A (e.g., a first UCIe-M I/O) that may be communicatively coupled to a first HBM channel 122A of the HBM device 82 and a second I/O interface 84B (e.g., a second UCIe-M I/O) that may be communicatively coupled to a second HBM channel 122B of the HBM device 82.

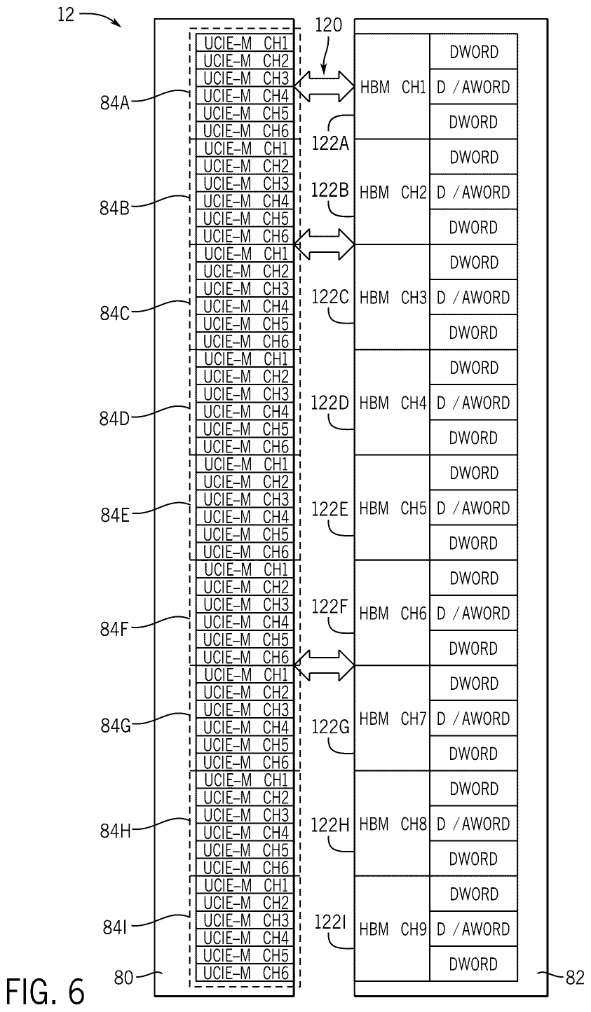

FIG. 6 is a schematic diagram of an example of the integrated circuit system 12 including an interface 120 between the integrated circuit device 80 and the HBM device 82. In the illustrated example, the HBM device 82 may include nine HBM channels 122 (illustrated as HBM channels 122A-I). To support communication with the nine HBM channels 122, the integrated circuit device 80 may include nine I/O interfaces 84 (illustrated as UCIe-M I/O 84A-I) that provide a total of 54 UCIe-M channels 124. As illustrated in FIGS. 4-6, the number of I/O interfaces 84 within the integrated circuit device 80 may be adjusted based on the number of HBM channels 122. The HBM devices 82 may also be stacked in the vertical direction, which may increase the number of HBM channels 122 that may be communicatively coupled to the integrated circuit device 80. As such, it should be understood that the number of I/O interfaces 84 within the integrated circuit device 80 may be adjusted based on the number of HBM devices 82 that may be communicatively coupled to the integrated circuit device 80.

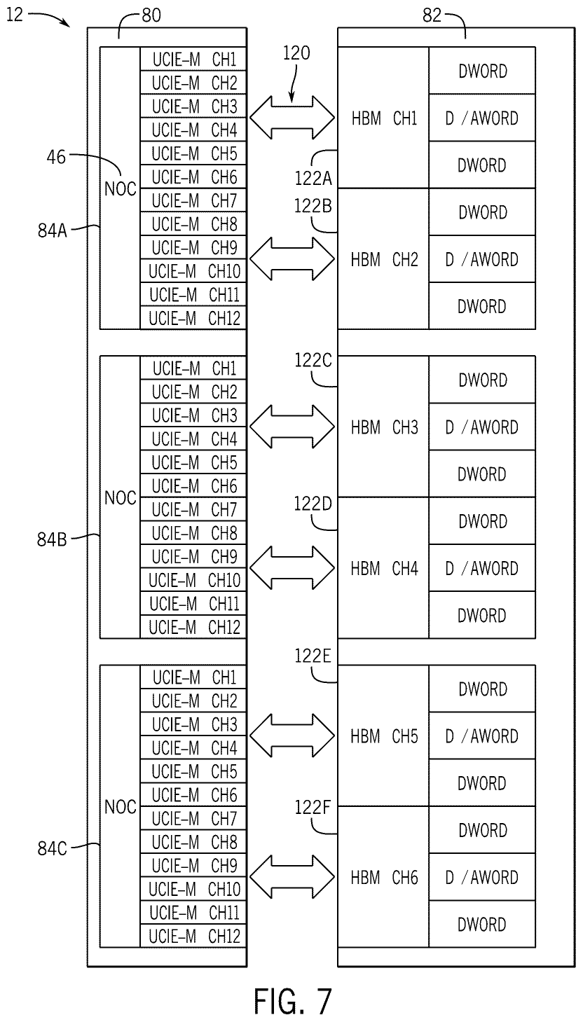

FIG. 7 is a schematic diagram of an example of the integrated circuit system 12 including an interface 120 between the integrated circuit device 80 and the HBM device 82. The HBM device 82 may include six HBM channels 122 (illustrated as HBM channels 122A-F). To support communication with the six HBM channels 122, the integrated circuit device 80 may include three I/O interfaces (illustrated as UCIe-M I/O 84A-F) that provide a total of 36 UCIe-M channels 124. In the illustrated example, each I/O interface 84 may include twelve UCIe-M channels 124. As such, each I/O interface 84 may transmit to and/or receive data from two HBM channels 122.

The I/O interface 84 may be communicatively coupled to the NOC 46 to facilitate data transfer between the I/O interface 84 and other components of the integrated circuit device 80. For example, the NOC 46 may facilitate data transfer between the I/O interface 84 and the programmable logic circuitry 30 of the integrated circuit device 80.

The integrated circuit device 80 of FIG. 7 may be designed by repeating the design of the I/O interface 84 along an edge of the integrated circuit device 80, on a face of the integrated circuit device 80, or any combination thereof. Repeating the design of the I/O interface 84 across the integrated circuit device 80 may increase the modularity of the design and/or decrease complexity of the design.

FIG. 7 is a schematic diagram of an example of the integrated circuit system 12 including an interface 120 between the integrated circuit device 80 and the HBM device 82. In particular, FIG. 7 illustrates an interface mapping view of operation in the UCIe-S mode and the UCIe-M mode for one UCIe-M channel 124 and one HBM channel 122. The data pins in the UCIe-M mode may include bidirectional pins, while data pins in the UCIe-S mode may include unidirectional pins.

The UCIe-M channel 124 may include a first UCIe-M channel interface 140A and a second UCIe-M channel interface 140B. The HBM channel 122 may include a first HBM channel interface 142A and a second HBM channel interface 142B. The first UCIe-M channel interface 140A and the first HBM channel interface 142A may be communicatively coupled and may transmit UCIe-M signals including data signals and clock signals. The first UCIe-M channel interface 140A and the first HBM channel interface 142A may communicate in the UCIe-M mode. In the UCIe-M mode, the integrated circuit device 80 and the HBM device 82 may communicate using DWORD communication, D/AWORD communication, and so on. The second UCIe-M channel interface 140B and the second HBM channel interface 142B may be communicatively coupled and may transmit UCIe-M signals including sideband signals. The second UCIe-M channel interface 140B and the second HBM channel interface 142B may communicate in the UCIe-S mode. In the UCIe-S mode, the integrated circuit device 80 and the HBM device 82 may communicate using the D/AWORD communication. The integrated circuit device 80 may also transmit and/or receive global signals and/or IEEE 5000 signals, or vice versa.

With the foregoing in mind, the HBM device 82 may use global signals and/or IEEE 5000 signals for controlling, assessing a mode of operation, and/or monitoring the HBM device 82. By way of specific example, Table 3 depicts a mapping of global signals and IEEE 5000 signals for the HBM device 82. For example, the HBM device 82 may include 196 HBM channel pins and 18 global/IEEE 5000 pins. To map to and/or communicate with these pins, the I/O interface 84 may include 6 UCIe-M channels 124 and 216 data/sideband pins. For example, the global pins may transmit and/or receive HBM signals including a reset signal, a Catastrophic Trip (CATTRIP) signal, a Temperature Status Bits [2:0] (TEMP [2:0]) signal. The HBM device 82 may transmit and/or receive one reset signal, three TEMP [2:0] signals and one CATTRIP signal. The global pins of the HBM device 82 may map to sideband signals and/or sideband pins of the UCIe-M channels 124. The IEEE 5000 signals may include a Write Scan In (WSI) signal and a Write Scan Out (WSO) signal, which may both map to sideband signals and/or sideband pins of the UCIe-M channels 124. The HBM device 82 may transmit and/or receive seven WSI signals and six WSO signals. As such, the HBM device 82 of the illustrative example may use eighteen global signals and IEEE 5000 signals during operation.

TABLE 3

| | | | Per HBM | | | UCIe-M Signal |
|---|---|---|---|---|---|---|
| Groups | HBM Signals | Direction | Total | Data | Clock | Mapping |
| Global | Reset | O | 1 | 1 | | Sideband |
| Signal | TEMP[2:0] | I | 3 | 3 | | Sideband |
| (GLB) | CATTRIP | I | 1 | 1 | | Sideband |
| IEEE | WSI | O | 7 | 7 | | Sideband |
| 5000 | WSO (follow | I | 6 (Assume | 6 (Assume | | Sideband |
| | channel | | 6 channels) | 6 channels) | | |
| | count) | | | | | |

| | | | |
|---|---|---|---|
| Total | 18 | 18 | 0 |

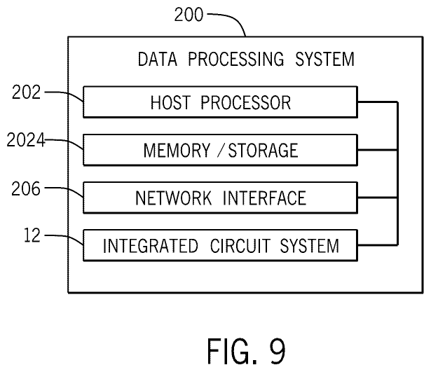

The processes discussed above may be carried out on the integrated circuit system 12, which may be a component included in a data processing system, such as a data processing system 200, shown in FIG. 9. The data processing system 200 may include the integrated circuit system 12, a host processor 202, memory and/or storage circuitry 204, and a network interface 206. The data processing system 200 may include more or fewer components (e.g., electronic display, user interface structures, application specific integrated circuits (ASICs)). The host processor 202 may include any of the foregoing processors that may manage a data processing request for the data processing system 200 (e.g., to perform elaboration and simulation, to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 204 may include random access memory (RAM), read-only memory (ROM), one or more hard drives, flash memory, or the like. The memory and/or storage circuitry 204 may hold data to be processed by the data processing system 200. In some cases, the memory and/or storage circuitry 204 may also store configuration programs (e.g., bitstreams, mapping function) for programming the integrated circuit system 12. The network interface 206 may allow the data processing system 200 to communicate with other electronic devices. The data processing system 200 may include several different packages or may be contained within a single package on a single package substrate. For example, components of the data processing system 200 may be located on several different packages at one location (e.g., a data center) or multiple locations. For instance, components of the data processing system 200 may be located in separate geographic locations or areas, such as cities, states, or countries.

The data processing system 200 may be part of a data center that processes a variety of different requests. For instance, the data processing system 200 may receive a data processing request via the network interface 206 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform] ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. An integrated circuit system, comprising:
a high bandwidth memory (HBM) device;
an integrated circuit device comprising an input/output (I/O) interface; and
a package substrate directly coupled to the HBM device and the I/O interface of the integrated circuited device via a plurality of package substrate bumps, wherein the package substrate comprises a first set of routing resources to transmit signals directly between the HBM device and the integrated circuit device and a second set of routing resources to couple the HBM device and the integrated circuit device to at least one ball grid array (BGA) ball.
EXAMPLE EMBODIMENT 2. The integrated circuit device of example embodiment 1, wherein the I/O interface comprises a Universal Chiplet Interconnect-Memory Input/Output (UCIe-M I/O).
EXAMPLE EMBODIMENT 3. The integrated circuit system of example embodiment 1, wherein the at least one BGA ball comprises at least two BGA balls.
EXAMPLE EMBODIMENT 4. The integrated circuit system of example embodiment 3, wherein a first set of BGA balls of the at least two BGA balls is configured to provide power to the HBM device and the integrated circuit device, and a second set of BGA balls of the at least two BGA balls is configured to provide grounding to the HBM device and the integrated circuit device.
EXAMPLE EMBODIMENT 5. The integrated circuit system of example embodiment 1, wherein the plurality of package substrate bumps comprises a set of microbumps of a plurality of microbumps, wherein at least a portion of the plurality of microbumps are depopulated based on the integrated circuit system comprising a standard package system.
EXAMPLE EMBODIMENT 6. The integrated circuit system of example embodiment 2, wherein the integrated circuit device is configured to communicate with the HBM device in a UCIe-M memory mode, a UCIe-S standard package mode, or both the UCIe-M memory mode and the UCIe-S standard package mode.
EXAMPLE EMBODIMENT 7. The integrated circuit system of example embodiment 2, wherein the UCIe-M I/O comprises a plurality of channels, the plurality of channels comprising a plurality of pins configured to facilitate bi-directional communications between the integrated circuit device and the HBM device.
EXAMPLE EMBODIMENT 8. The integrated circuit system of example embodiment 7, wherein a channel of the plurality of channels comprises a first UCIe-M channel interface and a second UCIe-M channel interface, wherein the first UCIe-M channel interface is configured for transmitting and receiving data signals or clock signals, and the second UCIe-M channel interface is configured for transmitting and receiving sideband signals.
EXAMPLE EMBODIMENT 9. The integrated circuit system of example embodiment 1, wherein the first set of routing resources facilitates the transmission of the signals between the integrated circuit device and the HBM device without an embedded multi-die interconnect bridge (EMIB) or an interposer.
EXAMPLE EMBODIMENT 10. An integrated circuit, comprising:
programmable logic circuitry; and
a Universal Chiplet Interconnect-Memory Input/Output (UCIe-M I/O) coupled to the programmable logic circuitry and a package substrate, wherein the UCIe-M I/O is directly coupled to the package substrate via a plurality of package substrate bumps, and the UCIe-M I/O is configured to transmit and receive signals over the package substrate.
EXAMPLE EMBODIMENT 11. The integrated circuit of example embodiment 10, comprising a network-on-chip to receive data from the UCIe-M I/O and transfer the data to the programmable logic circuitry.
EXAMPLE EMBODIMENT 12. The integrated circuit of example embodiment 10, comprising a protocol translator to translate data from a UCIe protocol to a second protocol associated with the programmable logic circuitry.
EXAMPLE EMBODIMENT 13. The integrated circuit of example embodiment 10, wherein the UCIe-M I/O is coupled to a high bandwidth memory (HBM) device via the package substrate, wherein the package substrate comprises a plurality of routing resources configured to facilitate communications between the UCIe-M I/O and the HBM device using a UCIe protocol.
EXAMPLE EMBODIMENT 14. The integrated circuit of example embodiment 13, comprising at least one additional UCIe-M I/O to communicate with the HBM device using the UCIe protocol.
EXAMPLE EMBODIMENT 15. The integrated circuit of example embodiment 13, wherein the UCIe-M I/O communicates with the HBM device using Data Word (DWORD) communications, Address/Data Word (D/A WORD) communications, or any combination thereof.
EXAMPLE EMBODIMENT 16. A communication bridge, comprising:
a plurality of package substrate bumps directly coupling the communication bridge to an integrated circuit device and a high bandwidth memory (HBM) device;
a first set of routing resources configured to facilitate a transmission of Universal Chiplet Interconnect—Memory (UCIe-M) signals between the integrated circuit device and the HBM device; and
a second set of routing resources configured to couple the integrated circuit device and the HBM device to a plurality of ball grid array (BGA) balls.
EXAMPLE EMBODIMENT 17. The communication bridge of example embodiment 16, wherein the first set of routing resources facilitate the transmission of UCIe-M signals between the integrated circuit device and the HBM device without an embedded multi-die interconnect bridge (EMIB) or an interposer.
EXAMPLE EMBODIMENT 18. The communication bridge of example embodiment 16, wherein the plurality of the package substrate bumps comprises controlled collapse chip connection (C4) bumps or a plurality of height-adjusted microbumps coupled to a bump pad.
EXAMPLE EMBODIMENT 19. The communication bridge of example embodiment 16, comprising the plurality of ball grid array (BGA) balls, wherein a first set of BGA balls of the plurality of BGA balls provides power to the integrated circuit device and the HBM device and a second set of BGA balls of the plurality of BGA balls provides grounding to the integrated circuit device and the HBM device.
EXAMPLE EMBODIMENT 20. The communication bridge of example embodiment 16, wherein the plurality of package substrate bumps is configured to facilitate bidirectional communications between the integrated circuit device and the HBM device.

What is claimed is:

1. An integrated circuit system, comprising:
a high bandwidth memory (HBM) device;
an integrated circuit device comprising an input/output (I/O) interface; and
a package substrate directly coupled to the HBM device and the I/O interface of the integrated circuited device via a plurality of package substrate bumps, wherein the package substrate comprises a first set of routing resources to transmit signals directly between the HBM device and the integrated circuit device and a second set of routing resources to couple the HBM device and the integrated circuit device to at least one ball grid array (BGA) ball.

2. The integrated circuit device of claim 1, wherein the I/O interface comprises a Universal Chiplet Interconnect—Memory Input/Output (UCIe-M I/O).

3. The integrated circuit system of claim 1, wherein the at least one BGA ball comprises at least two BGA balls.

4. The integrated circuit system of claim 3, wherein a first set of BGA balls of the at least two BGA balls is configured to provide power to the HBM device and the integrated circuit device, and a second set of BGA balls of the at least two BGA balls is configured to provide grounding to the HBM device and the integrated circuit device.

5. The integrated circuit system of claim 1, wherein the plurality of package substrate bumps comprises a set of microbumps of a plurality of microbumps, wherein at least a portion of the plurality of microbumps are depopulated based on the integrated circuit system comprising a standard package system.

6. The integrated circuit system of claim 2, wherein the integrated circuit device is configured to communicate with the HBM device in a UCIe-M memory mode, a UCIe-S standard package mode, or both the UCIe-M memory mode and the UCIe-S standard package mode.

7. The integrated circuit system of claim 2, wherein the UCIe-M I/O comprises a plurality of channels, the plurality of channels comprising a plurality of pins configured to facilitate bi-directional communications between the integrated circuit device and the HBM device.

8. The integrated circuit system of claim 7, wherein a channel of the plurality of channels comprises a first UCIe-M channel interface and a second UCIe-M channel interface, wherein the first UCIe-M channel interface is configured for transmitting and receiving data signals or clock signals, and the second UCIe-M channel interface is configured for transmitting and receiving sideband signals.

9. The integrated circuit of claim 1, wherein the first set of routing resources facilitates the transmission of the signals between the integrated circuit device and the HBM device without an embedded multi-die interconnect bridge (EMIB) or an interposer.

10. An integrated circuit, comprising:
programmable logic circuitry; and
a Universal Chiplet Interconnect—Memory Input/Output (UCIe-M I/O) coupled to the programmable logic circuitry and a package substrate, wherein the UCIe-M I/O is directly coupled to the package substrate via a plurality of package substrate bumps, and the UCIe-M I/O is configured to transmit and receive signals over the package substrate.

11. The integrated circuit of claim 10, comprising a network-on-chip to receive data from the UCIe-M I/O and transfer the data to the programmable logic circuitry.

12. The integrated circuit of claim 10, comprising a protocol translator to translate data from a UCIe protocol to a second protocol associated with the programmable logic circuitry.

13. The integrated circuit of claim 10, wherein the UCIe-M I/O is coupled to a high bandwidth memory (HBM) device via the package substrate, wherein the package substrate comprises a plurality of routing resources configured to facilitate communications between the UCIe-M I/O and the HBM device using a UCIe protocol.

14. The integrated circuit of claim 13, comprising at least one additional UCIe-M I/O to communicate with the HBM device using the UCIe protocol.

15. The integrated circuit of claim 13, wherein the UCIe-M I/O communicates with the HBM device using Data Word (DWORD) communications, Address/Data Word (D/AWORD) communications, or any combination thereof.

16. A communication bridge, comprising:
a plurality of package substrate bumps directly coupling the communication bridge to an integrated circuit device and a high bandwidth memory (HBM) device;
a first set of routing resources configured to facilitate a transmission of Universal Chiplet Interconnect—Memory (UCIe-M) signals between the integrated circuit device and the HBM device; and
a second set of routing resources configured to couple the integrated circuit device and the HBM device to a plurality of ball grid array (BGA) balls.

17. The communication bridge of claim 16, wherein the first set of routing resources facilitates the transmission of UCIe-M signals between the integrated circuit device and the HBM device without an embedded multi-die interconnect bridge (EMIB) or an interposer.

18. The communication bridge of claim 16, wherein the plurality of the package substrate bumps comprises controlled collapse chip connection (C4) bumps or a plurality of height-adjusted microbumps coupled to a bump pad.

19. The communication bridge of claim 16, comprising the plurality of ball grid array (BGA) balls, wherein a first set of BGA balls of the plurality of BGA balls provides power to the integrated circuit device and the HBM device and a second set of BGA balls of the plurality of BGA balls provides grounding to the integrated circuit device and the HBM device.

20. The communication bridge of claim 16, wherein the plurality of package substrate bumps is configured to facilitate bidirectional communications between the integrated circuit device and the HBM device.
